(19) United States
(12) Patent Application Publication
(10) Pub. No.: US 2021/0336184 A1
(43) Pub. Date: Oct. 28, 2021

(54) DISPLAY PANEL, DISPLAY DEVICE AND METHOD OF FABRICATING SAME

(71) Applicant: Ming Xiang, Wuhan (CN)

(72) Inventor: Ming Xiang, Wuhan (CN)

(73) Assignees: WUHAN CHINA STAR OPTOELECTRONICS SEMICONDUCTOR DISPLAY TECHNOLOGY CO., LTD., Wuhan (CN); WUHAN CHINA STAR OPTOELECTRONICS SEMICONDUCTOR DISPLAY TECHNOLOGY CO., LTD., Wuhan (CN)

(21) Appl. No.: 16/624,109

(22) PCT Filed: Oct. 8, 2019
(86) PCT No.: PCT/CN2019/109950

§ 371 Date: Dec. 18, 2019

(30) Foreign Application Priority Data
Jul. 25, 2019 (CN) 201910677214.5

(51) Int. Cl. H01L 51/52; H01L 27/32; H01L 51/56

(52) U.S. Cl. CPC H01L 51/5209; H01L 27/3234; H01L 51/5225; H01L 27/3246; H01L 51/56

(57) ABSTRACT

The present disclosure provides a display panel, a display device, and a display method thereof. The display panel includes a display area including: a light-emitting sub-area and an external light-transmitting sub-area; the display panel further includes: an anode, a light-emitting layer, a cathode, and a cover layer. The cover layer covers at least the light-emitting sub-area, and by patterning the covering layer, the normal electrical performance of each layer is ensured, and the transparent display effect of the display panel and the display device is improved.

### BACKGROUND OF INVENTION

### Field of Invention

The present invention relates to a field of display technologies, and in particular, to a display panel, a display device, and a method of fabricating the same.

### Description of Prior Art

Due to a high penetrability of the screen, the transparent display device can, on the one hand, transmit external light in front of the screen thereby implementing under-screen camera technology, and on the other hand, transmit external light behind the screen so that a user can see an object behind the screen. An organic light-emitting diode (OLED) display device is an ideal transparent display device because it does not require a backlight. For mainstream top-emitting OLED devices, a “transflective” cathode layer must be used to improve a light-existing efficiency and color purity. However, since the cathode is deposited on an entire surface of an open mask (OPM) by evaporation coating, penetration of the screen is lowered.

In order to improve the penetrability of the cathode, a cathode thinning or patterning scheme can be employed. For the cathode thinning scheme, a microcavity effect is attenuated, resulting in a decrease in light extraction efficiency and resulting in shifting of color coordinates at the same time, which impacts a normal display effect of the screen. For the cathode patterning scheme, in order to ensure that a common ground voltage signal can be input into the cathode of each pixel, it is still required that the cathodes on pixels are connected by a thin cathode trace, thereby increasing a cathode voltage drop and unevenness of the display. Therefore, how to improve the penetrability of the cathode without impacting the display effect of the screen becomes an urgent problem to be solved.

In summary, a conventional transparent display device has a problem that the cathode has low light penetration and poor display effect. Therefore, it is necessary to provide a display panel, a display device, and a method of fabricating the same to improve this defect.

### SUMMARY OF INVENTION

An embodiment of the present disclosure provides a display panel, a display device, and a method of fabricating the same, which are used to solve the problem of low light penetration and poor display effect of the cathode of the conventional transparent display device.

An embodiment of the present disclosure provides a display panel, including: a display area, the display area comprising: a light-emitting sub-area and an external light-transmitting sub-area, wherein the display panel comprises: an anode disposed in the light-emitting sub-area; a light-emitting layer disposed on the anode and located in the light-emitting sub-area; a cathode disposed on a side of the light-emitting layer away from the anode, and covering the display area; and a cover layer disposed on a side of the cathode away from the light-emitting layer, and covering at least the light-emitting sub-area

In accordance with an embodiment of the present disclosure, the cover layer covers only the light-emitting sub-area.

In accordance with an embodiment of the present disclosure, the cover layer covers the light-emitting sub-area and the external light-transmitting sub-area, and the cover layer in the light-emitting sub-area has a thickness greater than the cover layer in the external light-transmitting sub-area.

In accordance with an embodiment of the present disclosure, the display panel further comprises an image capturing component disposed on a side of the substrate away from the light-emitting layer.

An embodiment of the present disclosure provides a display device including a display panel, the display panel comprising: a display area, the display area comprising: a light-emitting sub-area and an external light-transmitting sub-area, wherein the display panel comprises: an anode disposed in the light-emitting sub-area; a light-emitting layer disposed on the anode and located in the light-emitting sub-area; a cathode disposed on a side of the light-emitting layer away from the anode, and covering the display area; and a cover layer disposed on a side of the cathode away from the light-emitting layer, and covering at least the light-emitting sub-area.

In accordance with an embodiment of the present disclosure, the cover layer covers only the light-emitting sub-area.

In accordance with an embodiment of the present disclosure, the cover layer covers the light-emitting sub-area and the external light-transmitting sub-area, and the cover layer in the light-emitting sub-area has a thickness greater than the cover layer in the external light-transmitting sub-area.

In accordance with an embodiment of the present disclosure, the display panel further comprises an image capturing component disposed on a side of the substrate away from the light-emitting layer.

Another embodiment of the present disclosure further provides a method of fabricating a display device, including: providing a substrate, the substrate comprising a display area, the display area comprising: a light-emitting sub-area and an external light-transmitting sub-area, wherein forming an anode, a pixel defining layer, a light-emitting layer, and a cathode sequentially on the substrate; forming a cover layer on a side of the cathode away from the substrate by evaporation coating, wherein the light-emitting layer is formed on a side of the anode away from the substrate, the cathode is formed on a side of the light-emitting layer away from the anode and covers the display area, and the cover layer at least covers the light-emitting sub-area.

In accordance with an embodiment of the present disclosure, the cover layer covers only the light-emitting sub-area.

In accordance with an embodiment of the present disclosure, a mask used for evaporation coating to form the cover layer is a fine metal mask.

In accordance with an embodiment of the present disclosure, the cover layer covers the light-emitting sub-area and the external light-transmitting sub-area, and the cover layer in the light-emitting sub-area has a thickness greater than the cover layer in the external light-transmitting sub-area.

In accordance with an embodiment of the present disclosure, the cover layer is formed by evaporation coating through a fine metal mask and an open mask, respectively.

Advantageous effects of the Invention: an embodiments of the present disclosure provides a cover layer on a side of a cathode away from a light-emitting layer, and the cover layer covers at least a light-emitting sub-area, and maintains a thickness of the cover layer on the cathode as original by patterning the cover layer, thereby ensuring normal electrical performance of each layer and a display effect of the display panel and the display device, enhancing light penetration of an external light-transmitting sub-area, and thus improving the transparent display effect of the display panel and the display device.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic cross-sectional view of a display panel according to Embodiment 1 of the present disclosure.

FIG. 2 is a schematic cross-sectional view of a display panel according to Embodiment 2 of the present disclosure.

FIG. 3 is a schematic flow chart of a method of fabricating a display device according to Embodiment 3 of the present disclosure.

FIG. 4A is a schematic cross-sectional view of a display device according to Embodiment 3 of the present disclosure.

FIG. 4B is a schematic cross-sectional view of a display device according to Embodiment 3 of the present disclosure.

FIG. 4C is a schematic cross-sectional view of a display device according to Embodiment 3 of the present disclosure.

FIG. 5 is a schematic cross-sectional view of a display device according to Embodiment 4 of the present disclosure.

### DETAILED DESCRIPTION OF PREFERRED EMBODIMENTS

The following description of the various embodiments is provided to illustrate the specific embodiments of the invention. Directional terms mentioned in the present invention, such as “vertical”, “horizontal”, “upper”, “bottom”, “pre”, “post”, “left”, “right”, “inside”, “outside”, “side”, etc., only refer to the direction of the additional drawing. Therefore, the directional terminology used is for the purpose of illustration and understanding of the invention. In the figures, structurally similar elements are denoted by the same reference numerals.

The disclosure will be further described below in conjunction with the accompanying drawings and specific embodiments:

### Embodiment 1

This embodiment of the present disclosure provides a display panel 100, which will be described in detail below with reference to FIG. 1.

As shown in FIG. 1, FIG. 1 is a schematic cross-sectional view of a display panel 100 according to an embodiment of the present disclosure. The display panel 100 includes a display area. The areas shown in FIG. 1 all belong to the display area. The display area includes a light-emitting sub-area A1 and an external light-transmitting sub-area A2, wherein the light-emitting sub-area A1 is used for the display panel to normally display the light-emitting effect, and the external light-transmitting sub-area A2 is used for providing a penetration path for external light when the display panel 100 does not perform a normally display function, thereby realizing the transparent display effect of the display panel 100.

In this embodiment, the display panel 100 includes a substrate 101, a buffer layer 102 disposed on the substrate 101, and a polysilicon layer 103 disposed on a side of the buffer layer 102 away from the substrate 101; a first gate insulating layer 104 on the buffer layer 102 and covering the polysilicon layer 103; a first gate line layer 105, a second gate insulating layer 106, and a second gate line layer 107 disposed on the first gate insulating layer 104 sequentially; an interlayer dielectric layer 108 disposed on a side of the second gate insulating layer 106 away from the substrate 101; a source/drain trace layer 109 disposed on a side of the interlayer dielectric layer 108 away from the substrate 101, wherein the source/drain trace layer 109 is connected to the polysilicon layer 103 through a via hole penetrating the interlayer dielectric layer 108, the second gate line layer 107, and the first gate line layer 105; and a planarization layer 110 disposed on the side of the interlayer dielectric layer 108 away from the substrate 101, wherein the planarization layer 110 covers the source/drain trace layer 109; and a pixel defining layer 112 is further disposed on a side of the planarization layer 110 away from the substrate 101.

As shown in FIG. 1, the display panel 100 further includes an anode 111 disposed in the light-emitting sub-area A1, and the anode 111 is disposed on the planarization layer 110 and connected to the source/drain trace layer 109 through a first via hole penetrating the planarization layer 110. The pixel defining layer 112 covers the anode 111, and the pixel defining layer 112 is provided with a via hole exposing the anode 111.

The display panel 100 further includes a light-emitting layer 113 disposed on the anode 111 and located in the light-emitting sub-area A1. The display panel 100 further includes a cathode 114 disposed on a side of the light-emitting layer 113 away from the anode 111 and covering the display area.

The display panel 100 further includes a cover layer 115 disposed on a side of the cathode 114 away from the light-emitting layer 113, and the cover layer 115 covers at least the light-emitting sub-area A1.

In this embodiment, as shown in FIG. 1, the cover layer 115 covers only the light-emitting sub-area A1, and a boundary of the cover layer 115 is kept aligned with a boundary of the light-emitting sub-area A1. The cover layer 115 disposed in the light-emitting sub-area A1 is configured to improve the light extraction efficiency of the light-emitting devices in each of the layers of the display panel 100, and improve the normal display effect of the display panel 100. Therefore, the cover layer is not provided in the external light-transmitting sub-area A2, to reduce refraction of the external light-transmitting sub-area A2 to the external light, thereby increasing the light transmittance of the external light-transmitting sub-area A2, and enhancing the transparency display effect of the display panel 100.

In some embodiments, the display panel 100 further includes image capturing components (not shown) disposed on a side of the substrate 101 away from the light-emitting layer 113, and external light can enter the image capturing components through the external light-transmitting sub-area A2 of the display panel 100, so that the under-screen camera technology can also be realized.

In this embodiment of the present disclosure, by patterning the cover layer 115, the cover layer 115 located in the light-emitting sub-area A1 is retained, and no cover layer is disposed in the external light-transmitting sub-area A2, thereby improving the external light penetration of the external light-transmitting sub-area A2, and maintaining an original thickness of the cathode 114 at the same time, that is, maintaining the original electrical properties of the cathode 114 and other layers, thus maintaining the original display effect of the display panel 100, while also enhancing the transparency display effect of the display panel 100.

### Embodiment 2

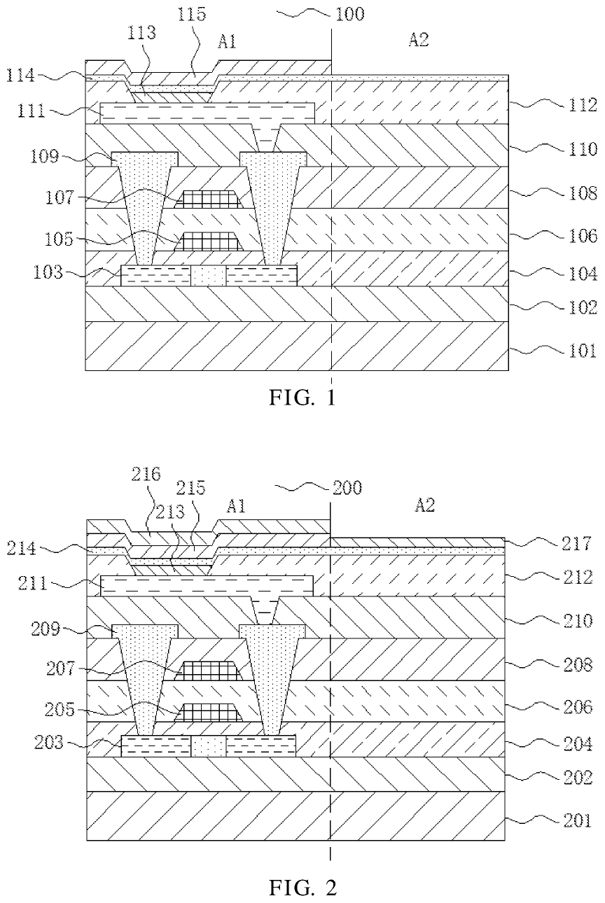

This embodiment of the present disclosure provides a display panel, which will be described in detail below with reference to FIG. 2.

As shown in FIG. 2, FIG. 2 is a schematic cross-sectional view of a display panel 200 according to an embodiment of the present disclosure. The display panel 200 includes a display area. The areas shown in FIG. 2 all belong to the display area. The display area includes a light-emitting sub-area A1 and an external light-transmitting sub-area A2, wherein the light-emitting sub-area A1 is used for the display panel to normally display the light-emitting effect, and the external light-transmitting sub-area A2 is used for providing a penetration path for external light when the display panel 200 does not perform a normal display function, thereby realizing the transparent display effect of the display panel 200.

In this embodiment, the display panel 200 includes a substrate 201, a buffer layer 202 disposed on the substrate 201, and a polysilicon layer 203 disposed on a side of the buffer layer 202 away from the substrate 201; a first gate insulating layer 204 on the buffer layer 202 and covering the polysilicon layer 203; a first gate line layer 25, a second gate insulating layer 206, and a second gate line layer 207 disposed on the first gate insulating layer 204 sequentially; an interlayer dielectric layer 208 disposed on a side of the second gate insulating layer 206 away from the substrate 201; a source/drain trace layer 209 disposed on a side of the interlayer dielectric layer 208 away from the substrate 201, wherein the source/drain trace layer 209 is connected to the polysilicon layer 203 through a via hole penetrating the interlayer dielectric layer 208, the second gate line layer 207, and the first gate line layer 205; and a planarization layer 120 disposed on the side of the interlayer dielectric layer 208 away from the substrate 201, wherein the planarization layer 210 covers the source/drain trace layer 209; and a pixel defining layer 212 is further disposed on a side of the planarization layer 210 away from the substrate 201.

As shown in FIG. 2, the display panel 200 further includes an anode 211 disposed in the light-emitting sub-area A1, and the anode 211 is disposed on the planarization layer 210 and connected to the source/drain trace layer 209 through a first via hole penetrating the planarization layer 210. The pixel defining layer 212 covers the anode 211, and the pixel defining layer 212 is provided with a via hole exposing the anode 211.

The display panel 200 further includes a light-emitting layer 213 disposed on the anode 211 and located in the light-emitting sub-area A1. The display panel 200 further includes a cathode 214 disposed on a side of the light-emitting layer 213 away from the anode 211 and covering the display area.

The cover layer covers the light-emitting sub-area A1 and the external light transmitting sub-area A2, and the cover layer in the light-emitting sub-area A1 has a thickness greater than the cover layer in the external light-transmitting sub-area A2.

As shown in FIG. 2, the cover layer includes a first cover layer 215, a second cover layer 216, and a third cover layer 217, and the first cover layer 215 and the second cover layer 216 are stacked on the light-emitting sub-area A1, boundaries of the first cover layer 215 and the second cover layer 216 are kept aligned with a boundary of the light-emitting sub-area A1, and the third cover layer 217 is disposed in the external light-transmitting sub-area A2. A sum of the thicknesses of the first cover layer 215 and the second cover layer 216 is greater than a thickness of the third cover layer 217. The first cover layer 215 and the second cover layer 216 disposed in the light-emitting sub-area A1 are configured to improve the light-extraction efficiency of the light-emitting devices in each of the layers of the display panel 200, and improve the normal display effect of the display panel 200. A purpose of designing the thickness of the third cover layer 217 to be smaller than the sum of the thicknesses of the first cover layer 215 and the second cover layer 216 is that the external light-transmitting sub-area A2 can be used to improve light-extraction efficiency of the internal light-emitting devices of the display panels when the display panel 200 is normally displayed, and can be used to reduce refraction of the external light-transmitting sub-area A2 to the external light when performing a transparent display function, thereby increasing the light transmittance of the external light-transmitting sub-area A2, and enhancing the transparent display effect of the display panel 200.

In some embodiments, the display panel 200 further includes image capturing components (not shown) disposed on a side of the substrate 201 away from the light-emitting layer 213, and external light can enter the image capturing components through the external light-transmitting sub-area A2 of the display panel 200, so that the under-screen camera technology can also be realized.

This embodiment of the present disclosure keeps the thickness of the third cover layer 217 in the external light-transmitting sub-area A2 by maintaining the original thicknesses of the first cover layer 215 and the second cover layer 216 in the light-emitting sub-area A1, thereby maintaining the original display effect of the display panel 200 and enhancing the external light transmittance of the external light-transmitting sub-area A2, thus improving the transparent display effect of the display panel 200.

### Embodiment 3

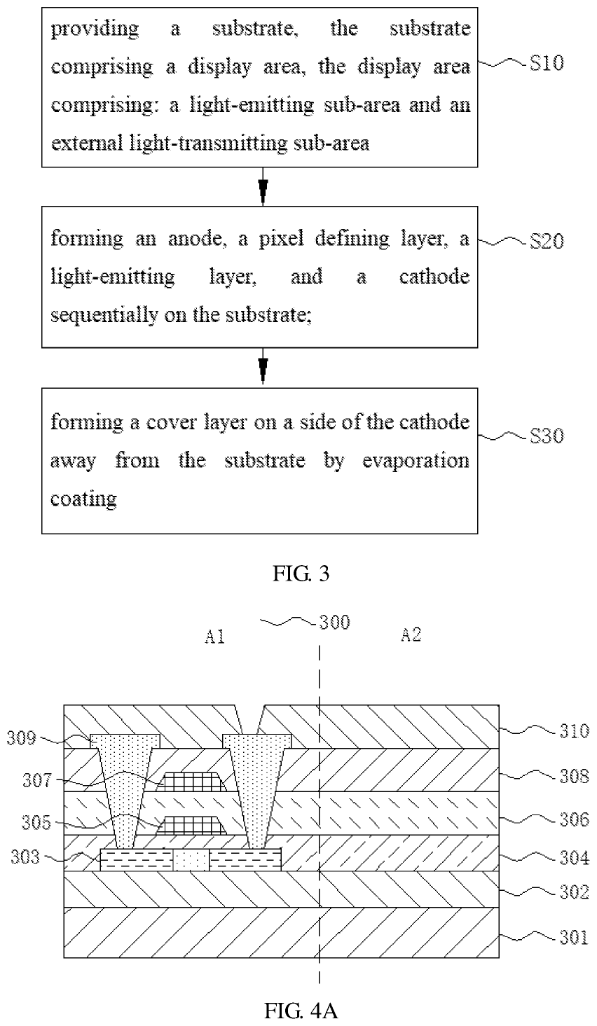

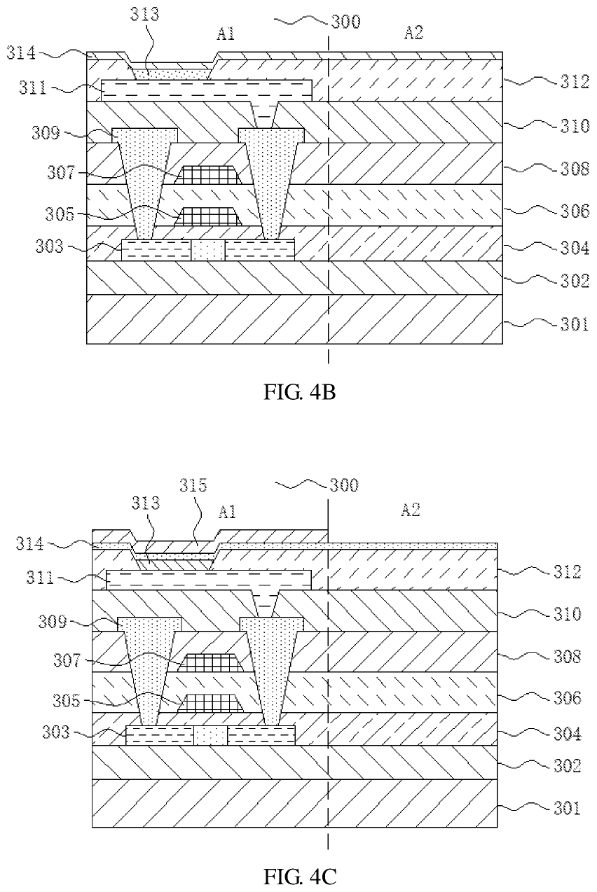

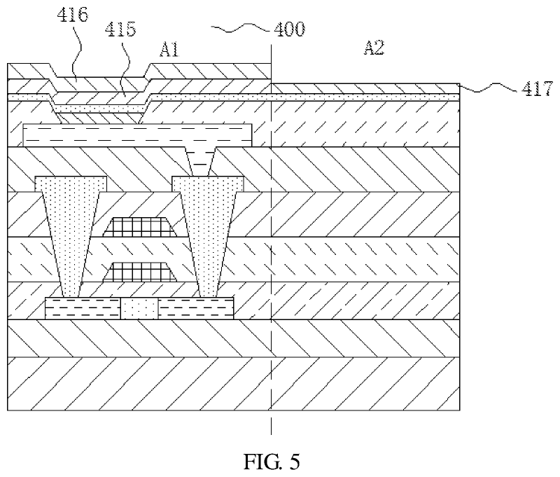

This embodiment of the present disclosure provides a method of fabricating the display device 300, which will be described in detail below with reference to FIG. 3, and FIG. 4A to FIG. 4C.

As shown in FIG. 3, FIG. 3 is a schematic flow chart of a method of fabricating a display device 300 according to an embodiment of the present disclosure, and FIG. 4A to FIG. 4C are schematic diagrams showing cross-sectional structures of a display device 300 according to an embodiment of the present disclosure. The method includes:

Step S10: providing a substrate 301, the substrate 301 comprising a display area, the display area comprising: a light-emitting sub-area A1 and an external light-transmitting sub-area A2. The areas shown in FIG. 4A all belong to the display area. The left side of the dotted line refers to the light-emitting sub-area A1, and the right side of the dotted line refers to the external light-transmitting sub-area A2, and the light-emitting sub-area A1 is used for the display panel to normally display the light-emitting effect, and the external light-transmitting sub-area A2 is used for providing a penetration path for external light.

Step S20: forming an anode 311, a pixel defining layer 312, a light-emitting layer 313, and a cathode 314 sequentially on the substrate 301. As shown in FIG. 4B, a pixel defining layer 312 covers the anode 312, and a via hole is formed in the pixel defining layer 312, the via hole exposing the anode 311 of the lower layer, and the light-emitting layer 313 is formed on the anode 311. The light-emitting layer 313 is formed on a side of the anode away from the substrate 301, the cathode 314 is formed on a side of the light-emitting layer away from the anode 311 and covers the display area. The anode 311 and the light-emitting layer 313 are both located in the light-emitting sub-area A1.

Step S30: forming a cover layer 315 on a side of the cathode 314 away from the substrate 301 by evaporation coating. As shown in FIG. 4C, the cover layer 315 covers only the light-emitting sub-area A1.

Specifically, in the step S30, a mask used for evaporation coating to form the cover layer 315 is a fine metal mask, and the cover layer is formed in the light-emitting sub-area A1 by evaporation coating through the fine metal mask, while a cover layer material is not evaporation coated in the external light transmitting area A2.

The cover layer 315 disposed in the light-emitting sub-area A1 is configured to improve the light-extraction efficiency of the light-emitting devices in each of the layers of the display panel 300, and improve the normal display effect of the display panel 300. Therefore, the cover layer is not provided in the external light-transmitting sub-area A2, to reduce refraction of the external light-transmitting sub-area A2 to the external light, thereby increasing the light transmittance of the external light-transmitting sub-area A2, and enhancing the transparency display effect of the display panel 300.

In this embodiment, before performing the step S10, the following steps are also required:

Step S101: providing a substrate 301, and forming a buffer layer 302 on the substrate 301 by deposition.

Step S102: forming a patterned polysilicon layer 303 on the buffer layer 302 by deposition and etching, and subjecting the patterned polysilicon layer 303 to a heavily ion doping to form a source/drain.

Step S103: forming a first gate insulating layer 304 on the buffer layer 302 by deposition, the first gate insulating layer 304 covering the source/drain, and forming a first metal gate layer 305 on the first gate insulating layer 304 by deposition and etching.

Step S104: forming a second gate insulating layer 306 on the first gate insulating layer 304 by deposition, the second gate insulating layer 306 covering the first metal gate layer 305, and forming a second metal gate layer 307 on the second gate insulating layer 306 by deposition and etching.

Step S105: forming an interlayer dielectric layer 308 on the second gate insulating layer 306 by deposition, forming a via hole penetrating the interlayer dielectric layer 308, the second gate insulating layer 306, and the first gate insulating layer 304 by etching, and forming a source/drain trace layer 309 on the interlayer dielectric layer 308 by deposition and etching, wherein the source/drain trace layer 309 is in contact with the source/drain through the via hole.

Step S106: forming a patterned organic planarization layer 310 on the source/drain trace layer 309 by coating, exposure, development, and curing.

By patterning the cover layer 315, the cover layer 315 located in the light-emitting sub-area A1 is retained, and no cover layer is disposed in the external light-transmitting sub-area A2, thereby improving the external light penetration of the external light-transmitting sub-area A2, and maintaining an original thickness of the cathode 314 at the same time, that is, maintaining the original electrical properties of the cathode 314 and other layers, thus maintaining the original display effect of the display panel 300, while also enhancing the transparency display effect of the display panel 300.

### Embodiment 4

This embodiment of the present disclosure provides a method of fabricating the display device 400, which is the same as the method of fabricating the display device 300 provided in the Embodiment 3, and has a structure substantially the same as the display device 300. The cover layer of the display device 400, which is composed of a first cover layer 415, a second cover layer 416, and a third cover layer 417, and the first cover layer 415 and the second cover layer 416 are stacked on the light-emitting sub-area. A1, and boundaries of the first cover layer 415 and the second cover layer 416 are kept aligned with a boundary of the light-emitting sub-area A1, and the third cover layer 417 is disposed in the external light-transmitting sub-area A2. A sum of the thicknesses of the first cover layer 215 and the second cover layer 416 is greater than a thickness of the third cover layer 417.

In the step S30, the first cover layer 415 is formed by evaporation coating through a fine metal mask and an open mask, respectively. Specifically, the first cover layer 415 is first formed by evaporation coating through the fine metal mask, and then the second cover layer 416 and the third cover layer 417 are formed by evaporation coating through an open mask.

In some embodiments, for a display device having a higher pixel density, a plurality of different fine metal masks may be used for evaporation coating. The display device includes a red sub-pixel unit, a green sub-pixel unit, and a blue sub-pixel unit, and the first fine metal mask is used to form the first cover layer on the red sub-pixel unit by evaporation coating, the second fine metal mask is used to form the first cover layer on the green sub-pixel unit and the blue sub-pixel unit by evaporation coating. The first fine metal mask is provided with a plurality of first openings corresponding to the red sub-pixel units, while the first fine metal mask has a closed structure corresponding to the green sub-pixel units and the blue sub-pixel units. The second fine metal mask is provided with a plurality of second openings corresponding to the green sub-pixel unit and the blue sub-pixel unit, while the second fine metal mask has a closed structure corresponding to the red sub-pixel uni.

This embodiment of the present disclosure keeps the thickness of the third cover layer 417 in the external light-transmitting sub-area A2 by maintaining the original thicknesses of the first cover layer 415 and the second cover layer 416 in the light-emitting sub-area A1, thereby maintaining the original display effect of the display panel 400 and enhancing the external light transmittance of the external light-transmitting sub-area A2, thus improving the transparent display effect of the display panel 400.

While the invention has been described by way of example and in terms of the preferred embodiments, it is to be understood that the invention is not limited to the disclosed embodiments. To the contrary, it is intended to cover various modifications and similar arrangements. Therefore, the scope of the appended claims should be accorded the broadest interpretation so as to encompass all such modifications and similar arrangements.

What is claimed is:

1. A display panel, comprising: a display area, the display area comprising: a light-emitting sub-area and an external light-transmitting sub-area, wherein
the display panel comprises:
an anode disposed in the light-emitting sub-area;
a light-emitting layer disposed on the anode and located in the light-emitting sub-area;
a cathode disposed on a side of the light-emitting layer away from the anode, and covering the display area; and
a cover layer disposed on a side of the cathode away from the light-emitting layer, and covering at least the light-emitting sub-area.

2. The display panel according to claim 1, wherein the cover layer covers only the light-emitting sub-area.

3. The display panel according to claim 1, wherein the cover layer covers the light-emitting sub-area and the external light-transmitting sub-area, and the cover layer in the light-emitting sub-area has a thickness greater than the cover layer in the external light-transmitting sub-area.

4. The display panel according to claim 1, wherein the display panel further comprises an image capturing component disposed on a side of the substrate away from the light-emitting layer.

5. A display device, comprising a display panel, the display panel comprising: a display area, the display area comprising: a light-emitting sub-area and an external light-transmitting sub-area, wherein
the display panel comprises:
an anode disposed in the light-emitting sub-area;
a light-emitting layer disposed on the anode and located in the light-emitting sub-area;
a cathode disposed on a side of the light-emitting layer away from the anode, and covering the display area; and
a cover layer disposed on a side of the cathode away from the light-emitting layer, and covering at least the light-emitting sub-area.

6. The display device according to claim 5, wherein the cover layer covers only the light-emitting sub-area.

7. The display device according to claim 5, wherein the cover layer covers the light-emitting sub-area and the external light-transmitting sub-area, and the cover layer in the light-emitting sub-area has a thickness greater than the cover layer in the external light-transmitting sub-area.

8. The display device according to claim 5, wherein the display panel further comprises an image capturing component disposed on a side of the substrate away from the light-emitting layer.

9. A method of fabricating a display device, comprising:
providing a substrate, the substrate comprising a display area, the display area comprising: a light-emitting sub-area and an external light-transmitting sub-area, wherein
forming an anode, a pixel defining layer, a light-emitting layer, and a cathode sequentially on the substrate;
forming a cover layer on a side of the cathode away from the substrate by evaporation coating, wherein
the light-emitting layer is formed on a side of the anode away from the substrate, the cathode is formed on a side of the light-emitting layer away from the anode and covers the display area, and the cover layer at least covers the light-emitting sub-area.

10. The method of fabricating according to claim 9, wherein the cover layer covers only the light-emitting sub-area.

11. The method according to claim 10, wherein a mask used for evaporation coating to form the cover layer is a fine metal mask.

12. The method according to claim 9, wherein the cover layer covers the light-emitting sub-area and the external light-transmitting sub-area, and the cover layer in the light-emitting sub-area has a thickness greater than the cover layer in the external light-transmitting sub-area.

13. The method according to claim 12, wherein the cover layer is formed by evaporation coating through a fine metal mask and an open mask, respectively.
